(19) United States
(12) Patent Application Publication
(10) Pub. No.: US 2025/0305119 A1
(43) Pub. Date: Oct. 2, 2025

(54) METHOD OF MANUFACTURING GAS BARRIER FILM

(71) Applicant: FUJIFILM Corporation, Tokyo (JP)

(72) Inventors: Yoshihiko MOCHIZUKI, Minamiashigara-shi (JP); Eijiro IWASE, Minamiashigara-shi (JP)

(73) Assignee: FUJIFILM Corporation, Tokyo (JP)

(21) Appl. No.: 19/238,885

(22) Filed: Jun. 16, 2025

Related U.S. Application Data
(63) Continuation of application No. PCT/JP2023/043766, filed on Dec. 7, 2023.

(30) Foreign Application Priority Data
Jan. 12, 2023 (JP) 2023-002918

(51) Int. Cl. C23C 16/34; C23C 16/02; C23C 16/44; C23C 16/455; C23C 16/50; C23C 16/52

(52) U.S. Cl. CPC C23C 16/345; C23C 16/0272; C23C 16/4412; C23C 16/45565; C23C 16/50; C23C 16/52

(57) ABSTRACT

Provided is a method of manufacturing a gas barrier film in which, in a case where a film is continuously formed on an elongated support through RtoR, abnormal discharge can be suppressed, and a gas barrier film having high gas barrier performance can be stably prepared. There is provided a method of manufacturing a gas barrier film, the method including: forming an inorganic layer on an elongated support or on an underlying organic layer on the support while transporting the support in a longitudinal direction, in which a plasma is generated by supplying raw material gas between the support and a conductor electrode having a porous structure that is disposed to face the support, and the inorganic layer is formed using a plasma chemical vapor deposition method, and before a main film forming step of forming the inorganic layer on the support or on the underlying organic layer on the support, a preliminary film forming step is provided, the preliminary film forming step being a step of forming an insulating inorganic layer having a lower density than the inorganic layer on a surface of the conductor electrode by setting power that is applied to the conductor electrode to be lower than power in the main film forming step while continuing the supply of the raw material gas and the application of the power until the main film forming step.

### CROSS-REFERENCE TO RELATED APPLICATIONS

This application is a Continuation of PCT International Application No. PCT/JP2023/043766 filed on Dec. 7, 2023, which claims priority under 35 U.S.C. § 119(a) to Japanese Patent Application No. 2023-002918 filed on Jan. 12, 2023. The above applications are hereby expressly incorporated by reference, in their entirety, into the present application.

### BACKGROUND OF THE INVENTION

### 1. Field of the Invention

The present invention relates to a method of manufacturing a gas barrier film.

### 2. Description of the Related Art

As a gas barrier film with high gas barrier performance, a gas barrier film where an underlying organic layer and an inorganic layer are laminated on a support is known. In order to form the inorganic layer of the gas barrier film, film formation by a vacuum film forming method (vapor phase deposition) such as plasma chemical vapor deposition (plasma CVD) is suitably used from the viewpoints of film properties (barrier properties) and productivity.

In addition, as a film forming method having high productivity, so-called roll-to-roll (hereinafter, referred to as RtoR) is known. As is well-known, RtoR is a film forming method of feeding a support from a roll where the elongated support is wound in a roll shape, forming a film while transporting the support in a longitudinal direction, and winding the support on which the film is formed in a roll shape again.

In addition, as the device that forms a film by plasma CVD through RtoR, a film forming device including an electrode pair consisting of a shower electrode and a cylindrical drum electrode is known.

In this film forming device, the drum electrode and the shower electrode are disposed to face each other, the elongated support is wound around the drum electrode, and while transporting the substrate in the longitudinal direction, a film is formed on the substrate by plasma CVD in a film forming region between the drum electrode and the shower electrode.

As is well known, the shower electrode is one kind of a gas supply electrode and includes, for example, a hollow portion and many openings communicating with the hollow portion. In the film forming device including the shower electrode, the shower electrode is disposed in a state where a formation surface of the opening faces the other electrode, and raw material gas is supplied to the hollow portion of the shower electrode to supply the raw material gas from the opening to the film forming region between the electrodes.

For example, JP2018-048386A describes a film forming device that forms a film on an elongated substrate by plasma CVD while transporting the substrate in a longitudinal direction, the film forming device including: a cylindrical drum electrode that transports the substrate wound around a peripheral surface; a shower electrode that configures an electrode pair with the drum electrode; a high frequency power supply that supplies plasma excitation power to the shower electrode; and a gas supply unit that supplies film forming gas, in which the gas supply unit supplies the film forming gas to the shower electrode, the shower electrode includes a plurality of openings in a discharge surface that is a surface facing the drum electrode to supply the film forming gas between the drum electrode and the shower electrode, further in a case where an area of the discharge surface is represented by As, a total area of the openings in the discharge surface is represented by Ah, and an area ratio between the area As of the discharge surface and the total area Ah of the openings is represented by Ah/(As−Ah), the shower electrode satisfies 0.0001<Ah/(As−Ah)<0.1, and in a case where the number of openings per 1 cm² of the discharge surface is represented by n, the shower electrode satisfies 0.2<n<25.

### SUMMARY OF THE INVENTION

In a case where a film is formed by plasma CVD, a film is deposited not only on the support on which the film should be formed but also on each of the units in the film forming device. In particular, in plasma CVD using the electrode pair such as capacitively coupled plasma CVD (CCP-CVD), a film is largely deposited on the facing surface of the electrode (shower electrode) on the side facing the support in the film-forming electrode pair for forming a plasma. Further, in RtoR, in order to continuously form the film, the amount of the film deposited on the electrode also increases.

Here, according to an investigation by the present inventors, it was found that, in a case where abnormal discharge (arc) occurs during film formation by plasma CVD through RtoR, a hole is formed in the inorganic layer or the support, which causes a decrease in gas barrier performance. In addition, not only the gas barrier film but also the drum electrode holding the support are damaged, which may also affect the gas barrier film that is subsequently formed. The present inventors thought that, in a case where a film is continuously formed on an elongated support through RtoR, it is important to suppress abnormal discharge from the viewpoint of stably manufacturing a gas barrier film.

An object of the present invention is to solve the above-described problem of the related art and to provide a method of manufacturing a gas barrier film in which, in a case where a film is continuously formed on an elongated support through RtoR, abnormal discharge can be suppressed, and a gas barrier film having high gas barrier performance can be stably prepared.

In order to achieve the object, the present invention has the following configurations.

[1] A method of manufacturing a gas barrier film, the method comprising:
forming an inorganic layer on an elongated support or on an underlying organic layer on the support while transporting the support in a longitudinal direction,
in which a plasma is generated by supplying raw material gas between the support and a conductor electrode having a porous structure that is disposed to face the support, and the inorganic layer is formed using a plasma chemical vapor deposition method, and
before a main film forming step of forming the inorganic layer on the support or on the underlying organic layer on the support, a preliminary film forming step is provided, the preliminary film forming step being a step of forming an insulating inorganic layer having a lower density than the inorganic layer on a surface of the conductor electrode by setting power that is applied to the conductor electrode to be lower than power in the main film forming step while continuing the supply of the raw material gas and the application of the power until the main film forming step.

[2] The method of manufacturing a gas barrier film according to [1],
in which the power that is applied to the conductor electrode in the preliminary film forming step is 20% to 50% of the power in the main film forming step.

[3] The method of manufacturing a gas barrier film according to [1] or [2],
in which during transition from the preliminary film forming step to the main film forming step, the power is changed stepwise from the power in the preliminary film forming step to the power in the main film forming step.

[4] The method of manufacturing a gas barrier film according to any one of [1] to [3],
in which a transportation speed of the support in the preliminary film forming step is slower than a transportation speed of the support in the main film forming step, and
during transition from the preliminary film forming step to the main film forming step, the transportation speed of the support is increased.

[5] The method of manufacturing a gas barrier film according to any one of [1] to [4],
in which a ratio of a density of the insulating inorganic layer to a density of the inorganic layer is 0.3 to 0.8.

[6] The method of manufacturing a gas barrier film according to any one of [1] to [5],
in which a ratio of a total area of holes to an area of a discharge surface of the conductor electrode is 0.005 to 0.2.

[7] The method of manufacturing a gas barrier film according to any one of [1] to [6],
in which a sprayed film having a surface roughness Ra of 1 μm to 20 μm is provided on a discharge surface of the conductor electrode.

[8] The method of manufacturing a gas barrier film according to any one of [1] to [7],
in which in the preliminary film forming step, particles are measured, and transition to the main film forming step starts along with an increase in particles.

[9] The method of manufacturing a gas barrier film according to [8],
in which in the preliminary film forming step, a particle monitor that measures the particles is mounted at a position distant from a film formation chamber where the formation of the inorganic layer is performed.

[10] The method of manufacturing a gas barrier film according to [9],
in which an exhaust pipe connected to the film formation chamber is branched and connected to the particle monitor to measure particles during exhaust.

[11] The method of manufacturing a gas barrier film according to [10],
in which a path length from the film formation chamber to the particle monitor is 0.5 m to 2 m.

[12] The method of manufacturing a gas barrier film according to any one of [1] to [11],
in which a temperature of the conductor electrode in the main film forming step is adjusted.

According to the present invention, it is possible to provide a method of manufacturing a gas barrier film in which, in a case where a film is continuously formed on an elongated support through RtoR, abnormal discharge can be suppressed, and a gas barrier film having high gas barrier performance can be stably prepared.

### BRIEF DESCRIPTION OF THE DRAWINGS

FIG. 1 is a diagram conceptually showing an example of a film forming device that performs a method of manufacturing a gas barrier film according to the present invention.

FIG. 2 is a conceptual diagram showing an example of the method of manufacturing a gas barrier film according to the present invention.

FIG. 3 is a conceptual diagram showing an example of the method of manufacturing a gas barrier film according to the present invention.

FIG. 4 is a cross sectional view conceptually showing an example of a shower electrode in the film forming device shown in FIG. 1.

FIG. 5 is a graph showing a relationship between a treatment time, power, and a transportation speed for describing an example of the method of manufacturing a gas barrier film according to the present invention.

### DESCRIPTION OF THE PREFERRED EMBODIMENTS

Hereinafter, a method of manufacturing a gas barrier film according to an embodiment of the present invention will be described in detail based on a preferred embodiment shown in the accompanying drawings.

In the present invention, numerical ranges represented by “to” include numerical values before and after “to” as lower limit values and upper limit values.

### Method of Manufacturing Gas Barrier Film

The method of manufacturing a gas barrier film according to the embodiment of the present invention comprises:
forming an inorganic layer on an elongated support or on an underlying organic layer on the support while transporting the support in a longitudinal direction,
in which a plasma is generated by supplying raw material gas between the support and a conductor electrode having a porous structure that is disposed to face the support, and the inorganic layer is formed using a plasma chemical vapor deposition method, and
before a main film forming step of forming the inorganic layer on the support or on the underlying organic layer on the support, a preliminary film forming step is provided, the preliminary film forming step being a step of forming an insulating inorganic layer having a lower density than the inorganic layer on a surface of the conductor electrode by setting power that is applied to the conductor electrode to be lower than power in the main film forming step while continuing the supply of the raw material gas and the application of the power until the main film forming step.

First, a configuration of a film forming device that performs the method of manufacturing a gas barrier film according to the embodiment of the present invention (hereinafter, also referred to as the manufacturing method according to the embodiment of the present invention) will be described.

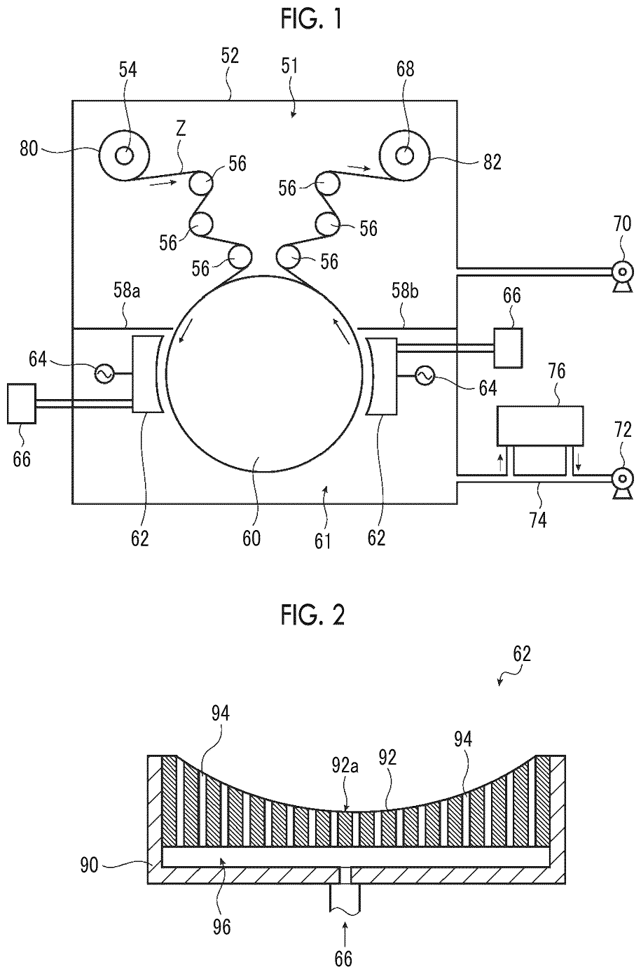

FIG. 1 conceptually shows an example of the film forming device that performs the method of manufacturing a gas barrier film according to the embodiment of the present invention.

A film forming device 50 shown in FIG. 1 is a device that performs the preliminary film forming step and the main film forming step in the present invention on an elongated support Z through roll-to-roll (hereinafter, also referred to as RtoR) while transporting the support Z in the longitudinal direction.

As is well known, RtoR is a manufacturing method including: feeding a sheet-shaped material from a roll around which an elongated sheet-shaped material is wound; performing film formation while transporting the elongated sheet in a longitudinal direction; and winding the sheet-shaped material on which the film is formed again in a roll shape. By using RtoR, high productivity and production efficiency can be obtained.

The film forming device 50 shown in FIG. 1 includes a vacuum chamber 52, an unwinding chamber 51 that is formed on an upper portion side of the vacuum chamber 52, a film formation chamber 61 that is formed on a lower portion side of the vacuum chamber 52, and a drum (drum electrode) 60 that is disposed in the vacuum chamber 52. In the film forming device 50, the upper portion and the lower portion are formed as shown in the drawing, which is irrelevant to the essence of the method of manufacturing a gas barrier film according to the embodiment of the present invention.

In the present invention, a film to be formed is not particularly limited, and all of the films that can be formed by capacitively coupled plasma (CCP)-CVD) can be used.

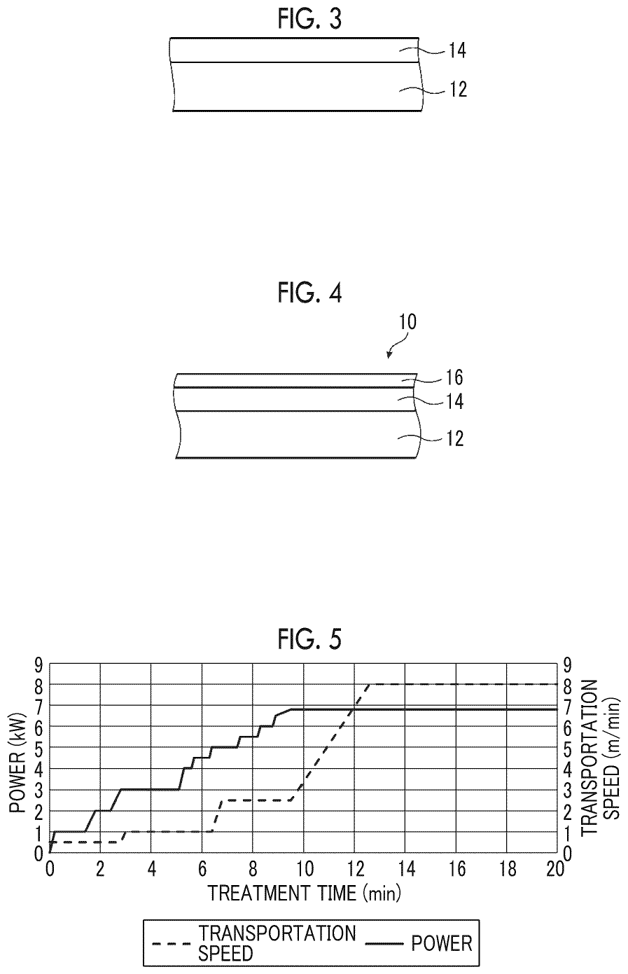

In addition, as the support Z that forms a film by the present invention, all of elongated sheet-shaped materials (webs) having flexibility, for example, a resin film, a laminate where an underlying organic layer 14 is formed on a resin film (support) 12 shown in FIG. 3, or a laminate where an organic layer and an inorganic layer are formed on the resin film can be used as long as they can be formed by CCP-CVD through RtoR.

In the film forming device 50, the elongated support Z is fed from a support roll 80 of the unwinding chamber 51, and a film is formed on the support Z by CCP-CVD in the film formation chamber 61 while transporting the support Z wound around a drum 60 in the longitudinal direction. Next, the support Z is transported to the unwinding chamber 51 and is wound around a winding shaft 68 to obtain a gas barrier film roll 82. In addition, in the unwinding chamber 51, a plurality of guide rollers 56 for transporting the support Z in a predetermined transport path are appropriately disposed.

The drum 60 is a cylindrical member and rotates about a center line of the cylinder counterclockwise in the drawing.

In the drum 60, the support Z guided in the predetermined path by the guide rollers 56 of the unwinding chamber 51 is wound around a predetermined region of the peripheral surface, is transported into the film formation chamber 61 in the longitudinal direction while being held in the predetermined position, and is transported to the guide rollers 56 of the unwinding chamber 51 again.

In the film forming device 50, the drum 60 acts as a counter electrode of a shower electrode 62 of the film formation chamber 61 described below. That is, the drum 60 and the shower electrode 62 configure an electrode pair for forming a film by CCP-CVD.

The drum 60 may be grounded as necessary, may be connected to a bias power supply for applying a bias, or may be connected to be switchable between the earth and the bias power supply. As the bias power supply, various well-known power supplies such as a high frequency power supply or a pulsed power supply that are used in a film forming device to apply a bias can be used.

Further, as necessary, the drum 60 may be equipped with a temperature control device for heating and/or cooling the support Z. As the temperature control device, various well-known temperature control devices such as a temperature control device using circulation of a temperature control medium, a temperature control device using a Peltier element, or a temperature control device using a heater can be used.

In the vacuum chamber 52, not only the above-described drum 60 but also partition walls 58a and 58b extending from an inner wall surface of the vacuum chamber 52 on the horizontal side to the vicinity of the peripheral surface of the drum 60 are disposed. The partition walls 58a and 58b approach the peripheral surface of the drum 60 at a position where tips (ends opposite to the inner wall surface of the vacuum chamber 52) are not in contact with the support Z that is transported.

The partition walls 58a and 58b and the drum 60 substantially airtightly separates the inside of the vacuum chamber 52 into the upper and lower sides. The upper side in the vacuum chamber 52 is the inner space (unwinding chamber) of the unwinding chamber 51, and the lower side in the vacuum chamber 52 is the inner space (film formation chamber) of the film formation chamber 61.

The unwinding chamber 51 includes the above-described winding shaft 68, the plurality of guide rollers 56, a rotating shaft 54, and an evacuation device 70.

The guide rollers 56 are typical guide rollers that guide the support Z in the predetermined transport path.

The rotating shaft 54 is a well-known rotating shaft that is charged with the support roll 80. On the other hand, the winding shaft 68 is a well-known elongated winding shaft that winds the support Z on which a film is formed to obtain the gas barrier film roll 82.

In the example shown in the drawing, the support roll 80 where the elongated support Z is wound in a roll shape is mounted on the rotating shaft 54. In addition, in a case where the support roll 80 is mounted on the rotating shaft 54, the support Z passes through the guide rollers 56 on the upstream side, the drum 60, and the guide rollers 56 on the downstream side and reaches the winding shaft 68, that is, passes through the predetermined path (is passed).

In the film forming device 50, by performing the feeding of the support Z from the support roll 80 and the winding of the support Z on which a film is formed in the winding shaft 68 in synchronization with each other, the film is formed in the film formation chamber 61 while transporting the elongated support Z in the predetermined transport path in the longitudinal direction.

The evacuation device 70 is a vacuum pump for reducing the pressure in the unwinding chamber 51 to obtain a predetermined degree of vacuum. The evacuation device 70 reduces the pressure in the unwinding chamber 51 to a pressure that does not affect the film formation in the film formation chamber 61.

As the evacuation device 70, various well-known evacuation devices that are used in a vacuum film forming device including a vacuum pump such as a turbopump, a mechanical booster pump, a rotary pump, or a dry pump can be used. Regarding this point, the same also applies to an evacuation device 72 of the film formation chamber 61 described below.

The film formation chamber 61 is formed below the unwinding chamber 51.

The film formation chamber 61 forms a film, for example, by CCP-CVD and includes the shower electrode 62, a gas supply unit 66, a high frequency power supply 64, and the evacuation device 72. In the example shown in FIG. 1, the film formation chamber 61 includes two sets including the shower electrode 62, the gas supply unit 66, and the high frequency power supply 64, which exhibit the same action, respectively.

As described above, the shower electrode 62 configures the electrode pair for forming a film by CCP-CVD together with the drum 60.

In addition, the shower electrode 62 acts as a supply unit of raw material gas for forming a film by CCP-CVD. That is, the shower electrode 62 supplies the raw material gas from the gas supply unit 66, and supplies the raw material gas between the shower electrode 62 and the drum 60 (support Z) from gas supply holes (through-holes) 94 (refer to FIG. 4) that are formed in a facing surface of the shower plate 92 facing the drum 60.

The shower electrode 62 is a conductor electrode having a porous structure in the present invention. In the example conceptually shown in FIG. 2, the shower electrode 62 includes a housing 90 forming an electrode main body and the shower plate 92. The shower electrode 62 is formed of a conductor. In the present invention, the conductor satisfies resistivity ρ<10⁻² Ωm.

The shower electrode 62 may include a frame-shaped grounding shield that is disposed to surround the electrode main body in a substrate surface direction to prevent abnormal discharge as necessary. The grounding shield consists of a conductive material and is grounded. Further, in order to more suitably prevent abnormal discharge, the grounding shield may include an insulating shield consisting of an insulating material to cover a facing surface of the frame facing the support Z.

In the present invention, as the housing 90 and the shower plate 92, basically, well-known housings and shower plates that are used in a film forming device or the like for CCP-CVD are used.

In the example shown in the drawing, the housing 90 is a rectangular housing where one of maximum surfaces is open. On the other hand, the shower plate 92 is a plate-shaped member including many through-holes 94 as gas supply holes.

The shower plate 92 is disposed to close the opening surface of the housing 90. In addition, in a state where the opening surface of the housing 90 is closed with the shower plate 92, a space 96 is formed in the shower electrode 62.

The shower electrode 62 may be formed by inserting the shower plate 92 into the opening surface of the housing 90 as in the example shown in the drawing, or may be formed by placing the shower plate 92 on the housing to close the opening surface of the housing.

Alternatively, by forming the shower plate in a housing shape where one surface is open, forming many through-holes as gas supply holes in the maximum surface of the housing, and placing or inserting a plate-shaped member into the opening surface of the shower plate to close the opening surface of the shower plate, an electrode main body including a space that communicates with the gas supply unit may be formed. In this case, the shower plate is disposed such that the supply surface of the through-holes faces the support Z.

The shower electrode 62 is disposed such that the shower plate 92 faces the support Z, that is, the drum 60. In a preferable aspect, a facing surface of the shower plate 92 facing the support Z has a recessed curved shape parallel to the peripheral surface of the drum 60.

As a material for forming the housing 90 and the shower plate 92, various well-known conductor materials such as stainless steel, aluminum, iron, magnesium, titanium, silicon carbide, nickel, chromium, tungsten, molybdenum, tantalum, niobium, and alloys thereof can be used. As the material for forming the housing 90 and the shower plate 92, stainless steel or aluminum is preferable.

The gas supply unit 66 is connected to the housing 90. The gas supply unit 66 is a well-known supply unit of raw material gas (process gas/film forming gas) used in a CVD device, and causes the raw material gas to flow into the space 96 of the shower electrode 62.

In addition, the high frequency power supply 64 is connected to the housing 90. The high frequency power supply 64 is also a well-known high frequency power supply used in a CVD device.

As described above, the support Z on which a film is formed by the film formation chamber 61 is supported and transported into the unwinding chamber 51 by the drum 60 again as described above, is guided in a predetermined direction by the guide rollers 56, and is wound around the winding shaft 68 to obtain the gas barrier film roll 82.

Hereinafter, the action of the film forming device 50 shown in FIG. 1 will be described.

The support roll 80 where the elongated support Z is wound in a roll shape is charged in the rotating shaft 54. The support Z is drawn from the support roll 80 and passes through the guide rollers 56 on the upstream side, the drum 60, and the guide rollers 56 on the downstream side and reaches the winding shaft 68, that is, passes through the predetermined path.

In a case where the support Z is inserted, the vacuum chamber 52 is closed and the evacuation devices 70 and 72 are driven to start the exhaust of each of the chambers.

After the unwinding chamber 51 and the film formation chamber 61 are exhausted to a predetermined degree of vacuum or lower, the gas supply unit 66 is driven to supply the raw material gas to the film formation chamber 61.

After the pressures in all of the chambers are stable at predetermined pressures, the driving of the drum 60 and the like is started to start the transport of the support Z. Further, while transporting the support Z in the longitudinal direction, a high frequency power supply 60 is driven to start forming a film on the support Z in the film formation chamber 61 such that the film is continuously formed on the elongated support Z.

As a result, for example, in a case where the laminate (refer to FIG. 3) of the support 12 consisting of the resin film and the underlying organic layer 14 is used as the support Z, as shown in FIG. 4, the elongated gas barrier film 10 where an inorganic layer 16 is formed on the underlying organic layer 14 in the laminate of the support 12 consisting of the resin film and the underlying organic layer 14 that is the support Z is obtained.

Here, in the manufacturing method according to the embodiment of the present invention, before a main film forming step of forming the inorganic layer 16 on the support 12 or on the underlying organic layer 14 on the support 12, a preliminary film forming step is provided, the preliminary film forming step being a step of forming an insulating inorganic layer having a lower density than the inorganic layer 16 on a surface of the conductor electrode by setting power that is applied to the conductor electrode (shower electrode 62) to be lower than power in the main film forming step while continuing the supply of the raw material gas and the application of the power until the main film forming step.

As described above, in a case where a film is formed by plasma CVD, a film is deposited not only on the support on which the film should be formed but also on each of the units in the film forming device. In particular, in plasma CVD using the electrode pair such as capacitively coupled plasma CVD (CCP-CVD), a film is largely deposited on the facing surface of the electrode (shower electrode) on the side facing the support in the film-forming electrode pair for forming a plasma. Further, in RtoR, in order to continuously form the film, the amount of the film deposited on the electrode also increases.

Here, according to an investigation by the present inventors, it was found that, in a case where abnormal discharge (arc) occurs during film formation by plasma CVD through RtoR, a hole is formed in the inorganic layer or the support, which causes a decrease in gas barrier performance. In addition, not only the gas barrier film but also the drum electrode holding the support are damaged, which may also affect the gas barrier film that is subsequently formed. The present inventors thought that, in a case where a film is continuously formed on an elongated support through RtoR, it is important to suppress abnormal discharge from the viewpoint of stably manufacturing a gas barrier film.

The present inventors further conducted an investigation and found that abnormal discharge is likely to occur at the very beginning of the film formation. Regarding this point, the present inventors thought that, in a case where an inorganic layer that is an insulator is formed on an electrode that is a conductive member, an in-plane distribution of the electric resistance on the electrode is generated such that a current intensively flows through a low-resistance portion, which leads to abnormal discharge. The present inventors thought that, in particular, in a case where the electrode is a shower electrode having a porous structure, or in a case where unevenness is present around holes or on the surface, for example, a sprayed film is formed on the surface, a deposition method of a film varies depending on positions such that an in-plane distribution of the electric resistance is likely to be generated, which leads to abnormal discharge.

On the other hand, it is considered to form an insulating coating on the surface of the shower electrode in advance. According to an investigation by the present inventors, it was found that the formation of the insulating coating having no holes (conductive spots) on the shower electrode having unevenness on the surface is practically impossible, and substantially insufficient formation of the insulating coating causes abnormal discharge due to electric field concentration at the start of discharge. Even in a case where the sufficient insulating coating can be formed on the surface of the shower electrode, in a case where the shower electrode on which the insulating coating is formed is cleaned (the film is peeled off) for reuse, it is assumed that the insulating film formed by CVD is also peeled off, and recoating is necessary for every peeling. In addition, stress is applied to the sprayed film due to the formation of the insulating coating, and the sprayed film is buckled due to the stress during the film formation, which causes a problem such as a defect of an inorganic layer.

On the other hand, the present inventors conducted a thorough investigation and thus found that, by sufficiently forming an insulating inorganic layer with low power on the shower plate having a conductive surface to completely cover the shower plate at the initial stage of the RtoR process, the occurrence of abnormal discharge can be suppressed, and subsequently an inorganic layer can be stably formed with high power.

That is, in the manufacturing method according to the embodiment of the present invention, before the main film forming step of forming the inorganic layer, the preliminary film forming step of forming the insulating inorganic layer having a lower density than the inorganic layer formed in the main film forming step on the surface of the conductor electrode with lower power than that of the main film forming step is provided. As a result, by transitioning to the main film forming step while continuing the supply of the raw material gas and the application of the power after performing the preliminary film forming step, the occurrence of abnormal discharge in the main film forming step can be suppressed. Accordingly, with the manufacturing method according to the embodiment of the present invention, a gas barrier film having high gas barrier performance can be stably prepared.

The raw material gas supplied in the main film forming step and the raw material gas supplied in the preliminary film forming step are basically the same kind of raw material gas. Therefore, the inorganic layer formed in the main film forming step and the inorganic layer formed in the preliminary film forming step are basically the same kind of inorganic layer. However, since the powers to be applied are different, the inorganic layers having different compositional ratios are formed in the main film forming step and the preliminary film forming step. For example, in a case where the inorganic layer to be formed is silicon nitride (SiN), examples of the raw material gas include silane gas, ammonia gas, and hydrogen gas. In this case, as the power to be applied decreases, the compositional ratio of hydrogen increases. Therefore, the low-density insulating inorganic layer is formed.

The amount of the raw material gas supplied in the preliminary film forming step and the amount of the raw material gas supplied in the main film forming step may be basically the same. The amount of the raw material gas supplied in the main film forming step may be set to be more than the amount of the raw material gas supplied in the preliminary film forming step. In this case, the amount of the raw material gas supplied may be adjusted such that the insulating inorganic layer can be appropriately formed on the conductor electrode in the preliminary film forming step. In addition, the amount of the raw material gas supplied may be adjusted such that the inorganic layer can be appropriately formed on the support in the main film forming step.

Since the insulating inorganic layer formed in the preliminary film forming step has a low density, the in-plane distribution of the electric resistance is relatively small even at the very beginning of the film formation. Therefore, it is considered that abnormal discharge is suppressed. In addition, the low-density insulating inorganic layer is less likely to be broken than the high-density inorganic layer formed in the main film forming step, and is less likely to be partially peeled off. Therefore, the occurrence of abnormal discharge at the position where the peeling occurs can be suppressed.

In addition, in a case where the main film forming step is performed by temporarily ending the application of power after forming the low-density insulating inorganic layer that should be formed in the preliminary film forming step on the surface of the shower electrode, a plasma is not stable immediately after the application of power, and thus abnormal discharge is likely to occur. On the other hand, in the manufacturing method according to the embodiment of the present invention, the transition from the preliminary film forming step to the main film forming step is performed while continuing the supply of the raw material gas and the application of power, that is, while performing the generation of a plasma. Therefore, the occurrence of abnormal discharge can be suppressed.

Here, from the viewpoint of suitably suppressing abnormal discharge, the power that is applied to the shower electrode (conductor electrode) in the preliminary film forming step is preferably 20% to 50% and more preferably 30% to 50% with respect to the power in the main film forming step.

In the main film forming step, the power that is applied to the shower electrode may be appropriately set depending on the kind of the plasma CVD method, the kind of the inorganic layer to be formed, the flow rate of gas to be introduced, the transportation speed, and the like. For example, the power that is applied to the shower electrode in the main film forming step is preferably 5 kW to 10 kW, more preferably 5.5 kW to 9 kW, and still more preferably 6 kW to 8 kW. Accordingly, the power that is applied to the shower electrode (conductor electrode) in the preliminary film forming step may be about 1 kW to 5 kW.

In addition, from the viewpoint of suitably suppressing abnormal discharge, it is preferable that the power is changed stepwise during the transition from the preliminary film forming step to the main film forming step. For example, it is preferable that the power is changed in about 5 steps to 10 steps during the transition from the preliminary film forming step to the main film forming step.

In addition, from the viewpoint of suitably suppressing abnormal discharge, it is preferable that the power is changed stepwise at the start of the preliminary film forming step to obtain a predetermined power.

FIG. 5 shows a graph showing a change in power during the transition from the preliminary film forming step to the main film forming step. FIG. 5 is a graph showing a relationship between the treatment time and the power.

In the example of the graph shown in FIG. 5, the power in the main film forming step is 6.8 kW, and the power in the preliminary film forming step is 3 kW. That is, the power in the preliminary film forming step is in a range of 20% to 50% with respect to the power in the main film forming step.

As shown in FIG. 5, at the start of the preliminary film forming step, the power is changed in three steps from 0 kW to 3 kW at an interval of 1 kW. In addition, as shown in FIG. 5, the power is maintained to be fixed for a predetermined time in each of the steps and is subsequently changed in the next step. The time for which the power is maintained to be fixed in each of the steps may be appropriately set depending on the transportation speed, the flow rate of gas to be introduced, and the like. In addition, the times for which the power is maintained to be fixed in the steps may be different from each other. In addition, in the example shown in FIG. 5, the power values increased in the respective steps are the same at 1 kW. However, the present invention is not limited thereto, and the power values may vary depending on the steps.

Next, the power is held at 3 kW for a predetermined time. As a result, the insulating inorganic layer having a low density is formed on the surface of the shower electrode. In a case where the insulating inorganic layer having a low density that has a thickness required for suppressing abnormal discharge is formed, the transition from the preliminary film forming step to the main film forming step starts.

In the example shown in FIG. 5, the power is changed from 3 kW to 6.8 kW in six steps. In addition, in the example shown in FIG. 5, the power is changed by 1 kW in the first stage, is changed at an interval of 0.5 kW, and is changed by 0.3 kW in the sixth step. During the transition from the preliminary film forming step to the main film forming step, the power values increased in the respective steps may be the same as or different from each other.

In addition, as shown in FIG. 5, the power is maintained to be fixed for a predetermined time in each of the steps and is subsequently changed in the next step. In addition, the times for which the power is maintained to be fixed in the steps may be the same as or different from each other.

The total time required for changing the power from the power in the preliminary film forming step to the power in the main film forming step is not particularly limited as long as abnormal discharge can be suppressed, and is preferably 1 minute to 10 minutes, more preferably 2 minutes to 9 minutes, and still more preferably 3 minutes to 8 minutes.

In the example shown in FIG. 5, the power is changed stepwise during the transition from the preliminary film forming step to the main film forming step. However, the present invention is not limited thereto, and the power may be continuously changed.

In addition, the preliminary film forming step and the main film forming step are performed while transporting the support. It is preferable that the transportation speed of the support in the preliminary film forming step is set to be slower than the transportation speed of the support in the main film forming step. In the preliminary film forming step, the insulating inorganic layer having a low density is also formed in the support but does not have desired gas barrier properties. Therefore, a portion of the support where the insulating inorganic layer having a low density is formed is not basically used. Accordingly, by setting the transportation speed of the support in the preliminary film forming step to be slower, the support that is not used can be reduced.

The transportation speed of the support in the main film forming step may be appropriately set depending on the thickness of the inorganic layer formed on the support, the heat resistance of the support, and the like.

In addition, the transportation speed of the support in the preliminary film forming step may be appropriately set depending on the heat resistance of the support, a speed controllable range of the device, and the like.

A ratio of a transportation speed of the support in the preliminary film forming step to a transportation speed of the support in the main film forming step is preferably 0.05 to 0.5, more preferably 0.08 to 0.45, and still more preferably 0.1 to 0.4.

The transportation speed may be changed stepwise as shown in FIG. 5 during the transition from the preliminary film forming step to the main film forming step. In addition, the transportation speed may be changed while changing the power from the power in the preliminary film forming step to the power in the main film forming step.

In addition, it is preferable that the transportation speed is changed to the transportation speed of the support in the main film forming step is performed after increasing the power to the power in the main film forming step. In a case where the transportation speed is changed, fluttering or the like of the support is likely to occur. Therefore, the formed plasma is unstable such that abnormal discharge is likely to occur. Therefore, in a case where the power and the transportation speed are simultaneously changed, abnormal discharge is likely to occur. Accordingly, by changing the transportation speed after increasing the power to the power in the main film forming step to stabilize the plasma, abnormal discharge can be suitably suppressed.

Here, from the viewpoint of suitably suppressing abnormal discharge, a ratio of the density of the insulating inorganic layer having a low density that is formed in the preliminary film forming step to the density of the inorganic layer that is formed in the main film forming step is preferably 0.3 to 0.8, more preferably 0.35 to 0.75, and still more preferably 0.4 to 0.7.

In a case where the density of the insulating inorganic layer having a low density that is formed in the preliminary film forming step is excessively high, Large-scale breakage of the inorganic layer formed in the preliminary film forming step or the main film forming step may be induced. On the other hand, in a case where the density of the insulating inorganic layer having a low density that is formed in the preliminary film forming step is excessively low, the insulating inorganic layer having a low density may be peeled off from the shower electrode due to the stress of the inorganic layer formed on the insulating inorganic layer having a low density in the main film forming step. On the other hand, by setting the range of the density of the insulating inorganic layer having a low density to be in the above-described range, the peeling of the inorganic layer from the shower electrode can be appropriately controlled.

Here, the density of the inorganic layer can be measured by X-ray reflectometry using the prepared gas barrier film and an X-ray diffractometer (for example, ATX-E, manufactured by Rigaku Corporation)

In addition, as the density of the insulating inorganic layer having a low density, the density of the insulating inorganic layer having a low density that is formed on the surface of the shower electrode may be obtained by measuring the density of the insulating inorganic layer formed on the support in the preliminary film forming step.

At a timing of the transition start from the preliminary film forming step to the main film forming step, a period of time for forming the insulating inorganic layer having a low density that has a thickness required for suppressing abnormal discharge may be measured in advance such that the transition to the main film forming step starts after the measured time from the start of the preliminary film forming step. Alternatively, in the preliminary film forming step, particles in the film formation chamber may be measured to start the transition to the main film forming step in a case where an increase in the particles is verified.

According to an investigation by the present inventors, it was found that, in a case where the insulating inorganic layer having a low density that has a sufficient thickness is formed on the shower electrode in the preliminary film forming step, partial peeling of the surface layer of the insulating inorganic layer starts such that particles occur. Accordingly, by detecting whether or not particles occur using a vacuum particle monitor, whether or not the shower electrode is coated with the insulating inorganic layer is detected to start the transition to the main film forming step. As a result, the transition to the main film forming step can be performed at an appropriate timing.

In the measurement using the particle monitor, dust and the like in the atmosphere are also counted as the particles. Therefore, a timing at which the number of particles measured using the particle monitor increases may be considered to be a timing at which the partial peeling of the surface layer of the insulating inorganic layer starts, that is, the insulating inorganic layer having a low density that has a sufficient thickness is formed on the shower electrode, and the transition to the main film forming step may start. Specifically, a steady state until the particles increase may be set as a reference such that the transition to the main film forming step starts at a timing at which the amount of particles detected is increased by 10% from the steady state.

As the particle monitor, for example, a commercially available particle monitor such as Stiletto manufactured by INFICON can be appropriately used.

Here, the particle monitor counts the size and/or number of particles in gas introduced into the equipment. Therefore, from this viewpoint, it is desirable that the particle monitor is mounted at a position as close as possible to a particle source (plasma or shower electrode). However, it was found that, in a case where the particle monitor is mounted at the position close to the particle source, there is a problem in that noise is included in the detection result due to an electromagnetic wave generated from the plasma. Therefore, it is preferable that the particle monitor is provided at a position distant from the film formation chamber 61 as shown in FIG. 1 instead of being provided in the film formation chamber that is a particle source or being provided close to the film formation chamber. In addition, as shown in FIG. 1, it is more preferable that an exhaust pipe 74 is branched halfway to introduce some of exhaust gas into a particle monitor 76 to detect particles such that the particle monitor 76 can stably perform the measurement.

From the above-described viewpoint of suppressing the noise and the viewpoint that the amount of particles reached can be appropriately detected without a decrease, a path length from the film formation chamber 61 to the particle monitor is preferably 0.5 m to 2 m and more preferably 0.5 m to 1 m.

In addition, from the viewpoint of more suitably detecting particles generated by the partial peeling of the surface layer of the insulating inorganic layer that occurs after forming the insulating inorganic layer having a low density that has a sufficient thickness, the size of particles detected by the particle monitor is preferably 1 μm or less, more preferably 0.1 μm to 1 μm, and still more preferably 0.2 to 1 μm.

In addition, for transition from the preliminary film forming step to the main film forming step at an appropriate timing, a sampling period of the particle monitor is preferably 5 minutes/times or less.

In addition, the detection of particles in the particle monitor may be performed in the main film forming step. In the main film forming step, particles having a number that is more than or equal to that detected in the preliminary film forming step can be detected. Accordingly, by detecting the particles in the main film forming step, the appropriate formation of the film can be verified.

In addition, as described above, in a case where the electrode is a shower electrode having a porous structure, a deposition method of a film varies depending on positions. Therefore, an in-plane distribution of the electric resistance is likely to be generated, and abnormal discharge is likely to occur. However, the manufacturing method according to the embodiment of the present invention can suitably suppress abnormal discharge, and thus is more suitably applicable to a case where a film is formed using a shower electrode having a porous structure. On the other hand, in a case where the proportion of holes is excessively large, the shower electrode cannot be sufficiently covered with the insulating inorganic layer having a low density. From the above-described viewpoint, the manufacturing method according to the embodiment of the present invention is suitably applicable to a ratio of the total area of holes to the area of a discharge surface of the conductor electrode is 0.005 to 0.2 and preferably 0.01 to 0.18.

Likewise, as described above, even in a case where a rough sprayed film is formed on the surface of the shower electrode, abnormal discharge is likely to occur. However, the manufacturing method according to the embodiment of the present invention can suitably suppress abnormal discharge, and thus is more suitably applicable to a case where a film is formed on the surface using a shower electrode including a sprayed film. On the other hand, in a case where a surface roughness Ra is excessively small, there is a concern that adhesion with the insulating inorganic layer having a low density cannot be sufficiently obtained. In addition, in a case where the surface roughness Ra is excessively large, the shower electrode cannot be sufficiently covered with the insulating inorganic layer having a low density. From the above-described viewpoint, the manufacturing method according to the embodiment of the present invention is suitably applicable to a case where a sprayed film having a surface roughness Ra of 1 μm to 20 μm and more preferably 2 μm to 17 μm is provided on the discharge surface of the conductor electrode.

In addition, the manufacturing method according to the embodiment of the present invention can suppress abnormal discharge, and thus is suitably applicable to a case where a gas barrier film is prepared by using a resin film having low heat resistance that is likely to be damaged due to abnormal discharge as the support. Specifically, the manufacturing method according to the embodiment of the present invention is suitably applicable to a case where a polyethylene terephthalate (PET) film, a polyethylene naphthalate (PEN) film, a cycloolefin polymer (COP) film, a triacetyl cellulose (TAC) film, or the like is used as the support.

Likewise, the manufacturing method according to the embodiment of the present invention is suitably applicable to a case where a gas barrier film is prepared using the support including the underlying organic layer having low heat resistance. Specifically, the manufacturing method according to the embodiment of the present invention is suitably applicable to a case where a gas barrier film is prepared using the support including the underlying organic layer formed of the following material having a glass transition temperature (Tg) of 250° C. or lower. Examples of the material having a glass transition temperature (Tg) of 250° C. or lower for forming the underlying organic layer include a (meth)acrylic resin mainly formed of a polymer such as a monomer, a dimer, or an oligomer of a bi- or higher functional (meth)acrylate such as dipropylene glycol di(meth)acrylate (DPGDA), trimethylolpropane tri(meth)acrylate (TMPTA), or dipentaerythritol hexa(meth)acrylate (DPHA).

In addition, in the manufacturing method according to the embodiment of the present invention, it is preferable that the film forming device includes a temperature control device that adjusts the temperature of the conductor electrode (shower electrode) to adjust the temperature of the conductor electrode in the main film forming step. In a case where the temperature of the shower electrode changes, the insulating inorganic layer is peeled due to a difference in thermal expansion between the shower electrode and the insulating inorganic layer formed on the shower electrode, which may lead to abnormal discharge. Accordingly, it is preferable that the temperature of the shower electrode in the main film forming step is adjusted to be substantially fixed. As the temperature control device, various well-known temperature control devices such as a temperature control device using circulation of a temperature control medium, a temperature control device using a Peltier element, or a temperature control device using a heater can be used.

The film forming method in the manufacturing method according to the embodiment of the present invention is not limited to CCP-CVD in the example shown in the drawing, and all of well-known plasma CVDs using a shower electrode, for example, microwave CVD can be used.

In addition, in the gas barrier film 10 shown in FIG. 4 that is prepared using the manufacturing method according to the embodiment of the present invention, a protective organic layer for protecting the inorganic layer may be further formed on the inorganic layer 16. Alternatively, the underlying organic layer and the inorganic layer may be formed again on the inorganic layer 16, and the protective organic layer may be further formed.

Hereinbefore, the method of manufacturing a gas barrier film according to the embodiment of the present invention has been described in detail. However, the present invention is not limited to the above-described aspects and various improvements and changes may be made within a range not departing from the scope of the present invention.

### EXAMPLES

Hereinafter, the present invention will be described in detail using Examples. The present invention is not limited to specific examples described below.

### Example 1

### <Support>

A polyethylene terephthalate film (PET film, manufactured by Toyobo Co., Ltd., trade name: A4300, thickness: 100 μm, width: 1000 mm, length 100 m) was prepared as the support, and an underlying organic layer was formed on a single surface side of the PET film in the following procedure.

### <Formation of Underlying Organic Layer>

TMPTA (manufactured by Daicel-Allnex Ltd.) and a photopolymerization initiator (ESACURE KTO 46, manufactured by Lamberti S.p.A.) were prepared and were weighed such that a weight ratio thereof was 95:5. These components were dissolved in methyl ethyl ketone. As a result, a coating liquid (composition for forming an organic layer) having a concentration of solid contents of 15% was obtained. This coating liquid was applied to the above-described PET film through RtoR using a die coater, and the substrate was allowed to pass through a drying zone at 50° C. for 3 minutes. Next, while being heated using a backup roll at 80° C., the coating film was irradiated and cured with ultraviolet rays (cumulative irradiation amount: about 600 mJ/cm²), and the laminate was wound. In this case, before contact with an initial film surface touch roll after the UV curing, a polyethylene protective film was bonded, and then the laminate was wound. The thickness of the underlying organic layer formed on the PET film was 2 μm.

### <Formation of Inorganic Layer>

Using a RtoR CVD device shown in FIG. 1, an inorganic layer (silicon nitride film) was formed on a surface of the underlying organic layer.

Specifically, the wound PET film with the underlying organic layer was fed, the protective film was peeled after passing through a final film surface touch roll before film formation, and the inorganic layer was formed on the exposed resin underlying organic layer. For the formation of the inorganic layer, silane gas (flow rate: 160 sccm), ammonia gas (flow rate: 370 sccm), hydrogen gas (flow rate: 590 sccm), and nitrogen gas (flow rate: 240 sccm) were used as raw material gas. As power supply, a silicon nitride film was formed using a high frequency power supply having a frequency of 13.56 MHz. The film formation pressure was 40 Pa, and the peak film thickness was 30 nm. Before contact with an initial film surface touch roll after the formation of the inorganic layer, a polyethylene protective film was bonded, and then the laminate was wound.

The raw material gas was introduced into the film formation chamber from through-holes of the shower electrode, and the above-described high frequency of 13.56 MHz was applied to the shower electrode to generate a plasma. By using aluminum as the material of the shower electrode, a roughened aluminum coating (sprayed film) was formed on the surface by thermal spraying. A ratio of the total area of the through-holes to the area of the discharge surface of the shower electrode was 0.012.

In addition, the film was formed by performing the main film forming step after the preliminary film forming step. The power of the preliminary film forming step was 3 kW, and the power of the main film forming step was 6.8 kW. In addition, by providing a particle monitor (Stiletto, manufactured by INFICON) in an exhaust pipe of the film formation chamber, particles in the preliminary film forming step were counted. After detecting that the number of particles was increased by 10% or more, the transition to the main film forming step was started. During the transition from the preliminary film forming step to the main film forming step, as shown in FIG. 5, the power was changed stepwise.

In addition, during the transition from the preliminary film forming step to the main film forming step, as shown in FIG. 5, the transportation speed was also changed.

The main film forming step was performed on the support having a length of 100 m as long as possible. As a result, during the preliminary film forming step to the main film forming step, abnormal discharge was not observed, and the inorganic layer was able to be appropriately formed.

### Example 2

A film was formed using the same method as that of Example 1, except that the transition to the main film forming step was started after performing the preliminary film forming step for 7 minutes without performing the detection of particles using the particle monitor. As a result, abnormal discharge was not observed while performing the preliminary film forming step and the main film forming step on the support having a length of 100 m, and the inorganic layer was able to be appropriately formed.

### Comparative Example 1

In a case where power of 6.8 kW was applied immediately after starting the film formation using the same method as that of Example 1 except that the preliminary film forming step was not performed, abnormal discharge occurred, and thus the film formation was stopped.

### Comparative Example 2

In a case where power of 6.8 kW was applied immediately after starting the film formation using the same method as that of Example 1 except that an electrode where a silicon oxide (SiO₂) film as an insulating film having a thickness of 1 μm was formed in advance by plasma CVD using a general vacuum film forming device on a surface of a sprayed film of the shower electrode was used as the shower electrode, and the preliminary film forming step was not performed, abnormal discharge occurred, and thus the film formation was stopped.

### Comparative Example 3

In a case where power of 6.8 kW was applied immediately after starting the film formation using the same method as that of Example 1 except that an electrode where Al₂O₃ treatment (insulation) was performed on a surface of a sprayed film of the shower electrode through an alumite treatment was used as the shower electrode, and the preliminary film forming step was not performed, abnormal discharge occurred, and thus the film formation was stopped.

As described above, it can be seen that the manufacturing method according to the embodiment of the present invention can suppress the occurrence of abnormal discharge. On the other hand, in Comparative Examples 1 to 3, abnormal discharge occurred during the application of power. In addition, even in a case where an insulating film was formed on the surface of the shower electrode in advance as in Comparative Examples 2 and 3, abnormal discharge occurred. The reason for this is presumed to be that the entire surface of the shower electrode was not able to be sufficiently covered such that abnormal discharge occurred due to concentration of an electric field on slightly exposed conductive portion

As can be seen from the above results, the effects of the present invention are obvious.

### EXPLANATION OF REFERENCES

10: gas barrier film
12: support (resin film)
14: underlying organic layer
16: inorganic layer
50: film forming device
51: unwinding chamber
52: vacuum chamber
54: rotating shaft
56: guide roller
58a, 58b: partition wall
60: drum (electrode)
61: film formation chamber
62: shower electrode (conductor electrode)
64: high frequency power supply
66: gas supply unit
68: winding shaft
70, 72: evacuation device
74: exhaust pipe
76: particle monitor
80: support roll
82: gas barrier film roll
90: housing
92: shower plate
94: through-hole
96: space

What is claimed is:

1. A method of manufacturing a gas barrier film, the method comprising:
forming an inorganic layer on an elongated support or on an underlying organic layer on the support while transporting the support in a longitudinal direction,
wherein a plasma is generated by supplying raw material gas between the support and a conductor electrode having a porous structure that is disposed to face the support, and the inorganic layer is formed using a plasma chemical vapor deposition method, and
before a main film forming step of forming the inorganic layer on the support or on the underlying organic layer on the support, a preliminary film forming step is provided, the preliminary film forming step being a step of forming an insulating inorganic layer having a lower density than the inorganic layer on a surface of the conductor electrode by setting power that is applied to the conductor electrode to be lower than power in the main film forming step while continuing the supply of the raw material gas and the application of the power until the main film forming step.

2. The method of manufacturing a gas barrier film according to claim 1,
wherein the power that is applied to the conductor electrode in the preliminary film forming step is 20% to 50% of the power in the main film forming step.

3. The method of manufacturing a gas barrier film according to claim 1,
wherein during transition from the preliminary film forming step to the main film forming step, the power is changed stepwise from the power in the preliminary film forming step to the power in the main film forming step.

4. The method of manufacturing a gas barrier film according to claim 1,
wherein a transportation speed of the support in the preliminary film forming step is slower than a transportation speed of the support in the main film forming step, and
during transition from the preliminary film forming step to the main film forming step, the transportation speed of the support is increased.

5. The method of manufacturing a gas barrier film according to claim 1,
wherein a ratio of a density of the insulating inorganic layer to a density of the inorganic layer is 0.3 to 0.8.

6. The method of manufacturing a gas barrier film according to claim 1,
wherein a ratio of a total area of holes to an area of a discharge surface of the conductor electrode is 0.005 to 0.2.

7. The method of manufacturing a gas barrier film according to claim 1,
wherein a sprayed film having a surface roughness Ra of 1 μm to 20 μm is provided on a discharge surface of the conductor electrode.

8. The method of manufacturing a gas barrier film according to claim 1,
wherein in the preliminary film forming step, particles are measured, and transition to the main film forming step starts along with an increase in particles.

9. The method of manufacturing a gas barrier film according to claim 8,
wherein in the preliminary film forming step, a particle monitor that measures the particles is mounted at a position distant from a film formation chamber where the formation of the inorganic layer is performed.

10. The method of manufacturing a gas barrier film according to claim 9,
wherein an exhaust pipe connected to the film formation chamber is branched and connected to the particle monitor to measure particles during exhaust.

11. The method of manufacturing a gas barrier film according to claim 10,
wherein a path length from the film formation chamber to the particle monitor is 0.5 m to 2 m.

12. The method of manufacturing a gas barrier film according to claim 1,
wherein a temperature of the conductor electrode in the main film forming step is adjusted.

13. The method of manufacturing a gas barrier film according to claim 2,
wherein during transition from the preliminary film forming step to the main film forming step, the power is changed stepwise from the power in the preliminary film forming step to the power in the main film forming step.

14. The method of manufacturing a gas barrier film according to claim 2,
wherein a transportation speed of the support in the preliminary film forming step is slower than a transportation speed of the support in the main film forming step, and
during transition from the preliminary film forming step to the main film forming step, the transportation speed of the support is increased.

15. The method of manufacturing a gas barrier film according to claim 2,
wherein a ratio of a density of the insulating inorganic layer to a density of the inorganic layer is 0.3 to 0.8.

16. The method of manufacturing a gas barrier film according to claim 2,
wherein a ratio of a total area of holes to an area of a discharge surface of the conductor electrode is 0.005 to 0.2.

17. The method of manufacturing a gas barrier film according to claim 2,
wherein a sprayed film having a surface roughness Ra of 1 μm to 20 μm is provided on a discharge surface of the conductor electrode.

18. The method of manufacturing a gas barrier film according to claim 2,
wherein in the preliminary film forming step, particles are measured, and transition to the main film forming step starts along with an increase in particles.

19. The method of manufacturing a gas barrier film according to claim 18,
wherein in the preliminary film forming step, a particle monitor that measures the particles is mounted at a position distant from a film formation chamber where the formation of the inorganic layer is performed.

20. The method of manufacturing a gas barrier film according to claim 19,
wherein an exhaust pipe connected to the film formation chamber is branched and connected to the particle monitor to measure particles during exhaust.
